(19) United States
(12) Patent Application Publication
(10) Pub. No.: US 2009/0137197 A1
(43) Pub. Date: May 28, 2009

(54) Outdoor unit of air conditioner

(76) Inventors: Seok Hoon Jang, Gimhae-si (KR); Byoung Sup Kim, Gimhae-si (KR); Joon Hyuk Kwon, Changwon City (KR); Woong Seok Noh, Namyangju-si (KR); Eun Seong Pack, Geumjeong-gu (KR)

Correspondence Address: MCKENNA LONG & ALDRIDGE LLP, 1900 K STREET, NW, WASHINGTON, DC, 20006, US

(21) Appl. No.: 12/081,403

(22) Filed: Apr. 15, 2008

(30) Foreign Application Priority Data
Nov. 23, 2007 (KR) 10-2007-0120356

(51) Int. Cl. H05K 5/00

(52) U.S. Cl. 454/184

(57) ABSTRACT

An outdoor unit for an air conditioner is provided. The outdoor unit has a control box in which a plurality of electronic components are installed. Electronic components from the components inside the control box that radiate the most heat are installed closer to a blower fan that forcibly circulates air.

The present application claims priority to Korean Patent Application No. 10-2007-0120356, filed Nov. 23, 2007, which is hereby incorporated by reference in its entirety.

### BACKGROUND

The present disclosure relates to an outdoor unit of an air conditioner having a control box with an internal configuration divided into multiple stages to separate the respective electrical components from one another.

In general, an air conditioner is a cooling/heating system that cools an indoor environment by continually performing a cycle of suctioning warm air from the indoor environment, performing heat exchange between the air and cold refrigerant, and expelling the cooled air back into the indoor environment. For heating, reverse conditions are employed to heat the indoor environment. The air conditioner performs sequential cycles using a compressor, condenser, expansion valve, and evaporator.

Such air conditioners may be divided largely into split system air conditioners with an outdoor unit and an indoor unit installed separately from each other, and integrated air conditioners with the outdoor unit integrally installed with the indoor unit.

A relatively recent phenomenon is the widespread use of multi unit air conditioners that are effectively applied in households wanting to install two or more air conditioners, and in buildings with multiple offices that respectively require an air conditioner. A multi unit air conditioner connects one outdoor unit to a plurality of indoor units to achieve the same effect as installing a plurality of split system air conditioners.

In the different types of air conditioners described above, a plurality of electrical components is housed in a control box within the outdoor unit. Such control boxes may not be able to perform their functions properly due to excessive heat they may radiate.

Also, because the electrical components are arranged side by side along a single surface within the control box, each component is affected by heat generated from other neighboring components. Such an arrangement also makes product assembly difficult.

### SUMMARY

Embodiments provide an outdoor unit of an air conditioner with a control box partitioned into a plurality of installation spaces to separate each electronic component.

Embodiments also provide an outdoor unit of an air conditioner that enables a control box to be hooked and fixed onto a frame assembly provided within a cabinet.

Embodiments further provide an outdoor unit of an air conditioner with a control box provided with a catching rib and a fastening end to facilitate fastening of the control box.

In one embodiment, an outdoor unit of an air conditioner includes: a control box including a plurality of built-in electronic components, wherein those of the electronic components generating more heat are installed in proximity to a blower fan that forcibly circulates air.

In another embodiment, an outdoor unit for an air conditioner, includes: a front panel defining a front exterior of the outdoor unit; and a control box in which a plurality of electronic components is disposed, wherein the front panel defines a servicing window to allow manipulation of the control box from a front exterior, and the control box is provided with an inspection window at a front surface thereof to enable inspection of a state of the air conditioner.

In a further embodiment, an outdoor unit for an air conditioner, includes: a cabinet defining an overall exterior of the outdoor unit; a blower fan forcing an upward discharging of air; a frame assembly provided within the cabinet to support the blower fan; and a control box provided at a side of the frame assembly, and including a plurality of electronic components within, wherein the control box is hooked and fixed to the frame assembly.

In an outdoor unit of an air conditioner according to the present disclosure, the inside of a control box is partitioned into a plurality of compartments to install electrical components in positions separated from one another. Accordingly, effects of heat generated by each electrical component on other components are reduced. Also, because assembly, repair and maintenance can be performed separately for each component, work efficiency can be improved.

Further, the top end of the control box according to the present disclosure is hooked and fixed onto the frame assembly, and a catch rib and a fastening end are provided on the top end of the control box. Thus, to fasten the control box, the top end thereof is first hooked onto the frame assembly, after which a screw may be used for fastening, thereby making installation easier.

The details of one or more embodiments are set forth in the accompanying drawings and the description below. Other features will be apparent from the description and drawings, and from the claims.

### BRIEF DESCRIPTION OF THE DRAWINGS

FIG. 1 is a perspective view of an outdoor unit according to a preferred embodiment of the present disclosure.

FIG. 2 is an exploded perspective view of an outdoor unit according to a preferred embodiment of the present disclosure.

FIG. 3 is right-side view of an installed control box according to an embodiment of the present disclosure.

FIG. 4 is a diagram showing a front panel of a control box.

FIG. 5 is a perspective view showing the internal structure of a control box according an embodiment of the present disclosure.

FIG. 6 is an exploded perspective view showing the internal structure of a control box according to an embodiment of the present disclosure.

FIG. 7 is an exploded perspective view showing the internal structure of a control box according to another embodiment of the present disclosure.

### DETAILED DESCRIPTION OF THE EMBODIMENTS

Reference will now be made in detail to the embodiments of the present disclosure, examples of which are illustrated in the accompanying drawings.

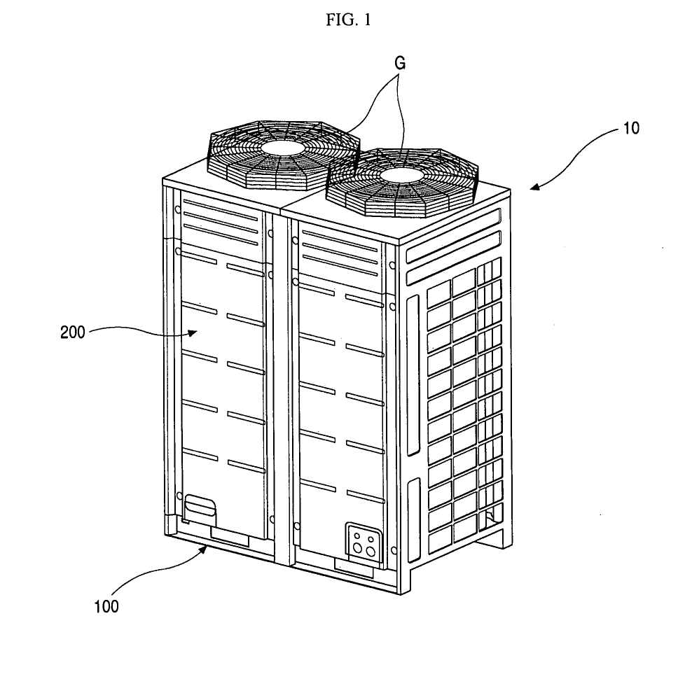

FIG. 1 is a perspective view of an outdoor unit according to a preferred embodiment of the present disclosure. Specifically, FIG. 1 exemplarily shows a type of outdoor unit for an air conditioner that discharges air upwards.

As shown in FIG. 1, the outdoor unit 10 has a hexahedral exterior shape and is connected through pipes to a plurality of indoor units (not shown). Refrigerant flows between the outdoor unit and indoor units.

The outdoor unit 10 has its lower exterior defined by a base assembly 100, and includes a cabinet 200 provided above the base assembly 100 to form the remaining exterior thereof. Also, outlet grills G have an octagonal shape (when viewed from above) and protrude upward from the top of the cabinet 200 to discharge air upward through the outlet grills G.

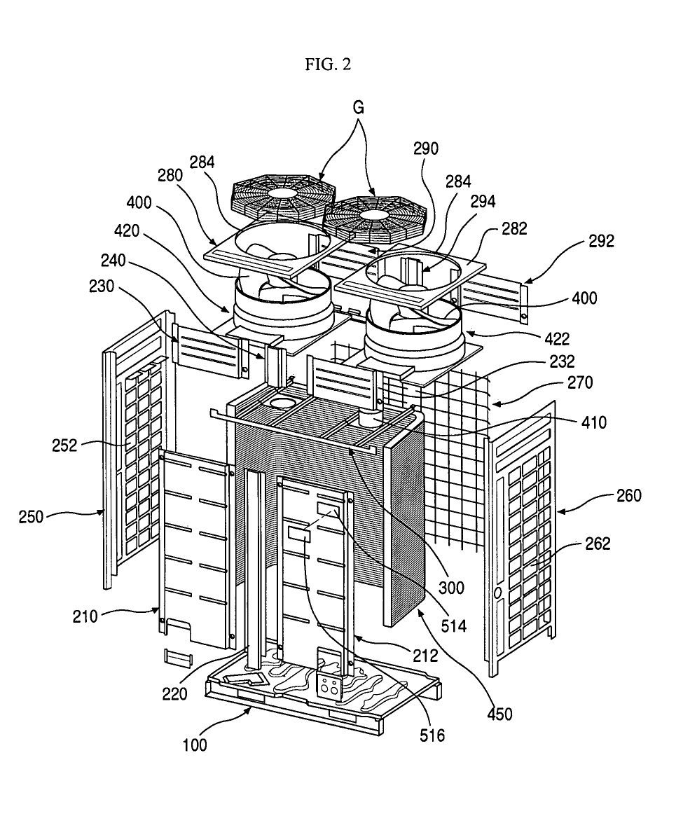

FIG. 2 is an exploded perspective view of an outdoor unit 10 according to a preferred embodiment of the present disclosure.

As shown in FIG. 2, the cabinet 200 is formed with a plurality of panels. In more detail, a pair of front panels 210 and 212 is provided at the front end of the base assembly 100 to define the front exterior of the outdoor unit. That is, a front left panel 210 and a front right panel 212, which have shapes of rectangular flat plates, are provided as a pair installed on the left and right, and a front center frame 220 is vertically elongated between the front left panel 210 and the front right panel 212.

A pair of front upper panels 230 and 232 is further provided above the pair of front panels 210 and 212. The front upper panels 230 and 232 form the front upper exterior of the outdoor unit, and include a front upper left panel 230 and a front upper right panel 232 at the left and right, respectively. A front upper frame 240 is further provided between the front upper left panel 230 and the front upper right panel 232. The front upper frame 240 is shaped correspondingly to the front center frame 220, and supports the pair of front upper panels 230 and 232.

A left panel 250 and a right panel 260 are provided at the left and right ends, respectively, of the base assembly 100, defining the left and right external facets of the outdoor unit. Also, a left grill 252 is integrally formed with the left panel 250, and a right grill 262 is integrally formed with the left panel 260. Thus, outside air is able to enter the outdoor unit 10 through left grill 252 and the right grill 262.

A pair of rear grills 270 is provided at the upper rear end of the base assembly 100. The rear grills 270 define the rear exterior surface, and air enters the outdoor unit 10 from the rear thereof through the rear grills 270.

A rear center frame (not shown) is further provided at the central portion of the pair of rear grills 270 opposite the front center frame 220 to support the pair of rear grills 270.

A pair of top panels 280 and 282 is provided between the top ends of the left panel 250 and the right panel 260 to define the top exterior of the outdoor unit. That is, the external top surface of the outdoor unit 10 is defined by the rectangular left top panel 280 and right top panel 282. An outlet 284 is defined vertically through each of the pair of top panels 280 and 282.

Also, the outlet grills (G) are installed on the outlets 284. The outlet grills (G) prevent impurities from the outside from entering through the outlets 284, and also allow air inside to be discharged upwards.

A pair of rear upper panels 290 and 292 is further provided at the top of the pair of rear grills 270. The rear upper panels 290 and 292 define the rear upper exterior of the outdoor unit, and are formed to correspond in shape to the front upper panels 230 and 232.

Accordingly, the rear upper panels 290 and 292 include a rear upper left panel 290 and a rear upper right panel 292 at the left and right sides, and a rear upper frame 294 is further provided between the rear upper left panel 290 and the rear upper right panel 292. The rear upper frame 294 is formed in a shape corresponding to the front upper frame 240, and supports the pair of rear upper panels 290 and 292.

A frame assembly 300 is provided within the cabinet 200. The frame assembly 300 is for supporting shrouds 420 and 422, a blower fan 400, and other components (to be described below), and is installed on the top ends of the front panels 210 and 212.

A pair of blower fan 400 and fan motor 410 assemblies is installed at the top of the frame assembly 300. The pair of blower fans 400 is enclosed by a pair of shrouds 420 and 422. That is, a left shroud 420 and a right shroud 422 having the same shape are installed at the top of the frame assembly 300, and a blower fan 400 is disposed to the inside of the pair of shrouds 420 and 422.

A heat exchanger 450 is installed within the cavity 200. The heat exchanger 450 functions to exchange heat between refrigerant flowing therein and air from the outside, and is installed on the upper left end, rear end, and right end of the base assembly 100. That is, the heat exchanger 450 is formed in a ‘∩’, shape as shown (when viewed from above).

A servicing window 514, allowing manipulation of a control box 500 (described below) from outside the front, is formed on the front panels 210 and 212, or specifically, on the front right panel 212. That is, as shown, a rectangular servicing window 514 is formed through the front right panel from the front to rear thereof.

Also, the servicing window 514 is selectively sealed by a servicing cover 516. The servicing cover 516 has a shape and size corresponding to the size and shape of the servicing window 514. That is, it is a rectangular plate corresponding in size to the servicing window 514.

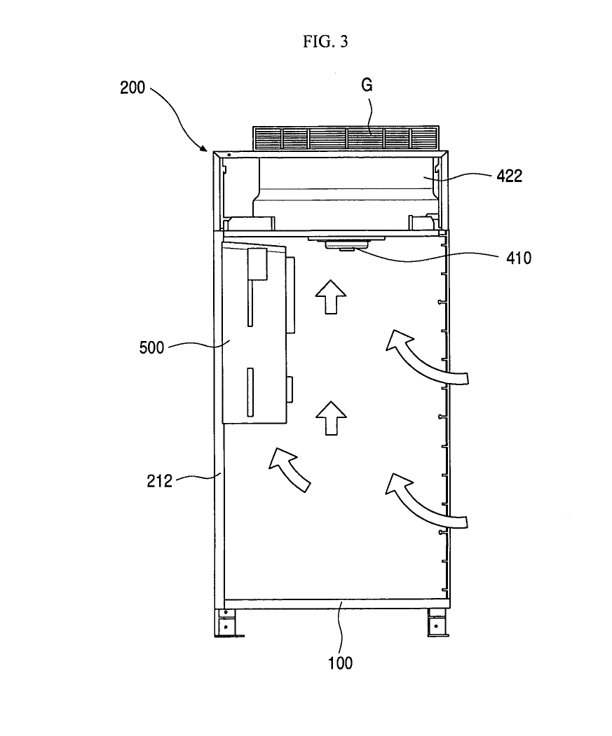

FIG. 3 is a right-side sectional view of a control box 500 installed the cabinet 200 according to an embodiment of the present disclosure.

As shown in FIG. 3, the control box 500 is installed rearward of the front panels 210 and 212. The control box 500 is a portion that controls the operation of the air conditioner, and has a plurality of electronic components within. Also, the blower fans 400 are disposed above the control box 500. Therefore, after air outside the outdoor unit 10 enters the outdoor unit 10, it is discharged upward, as shown in FIG. 3.

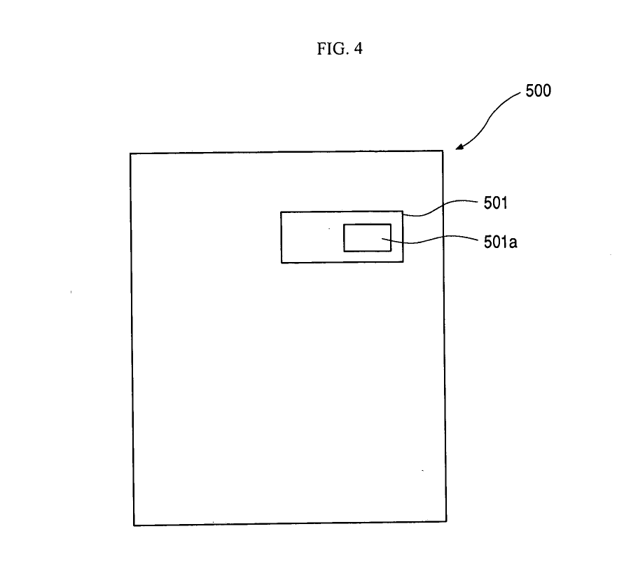

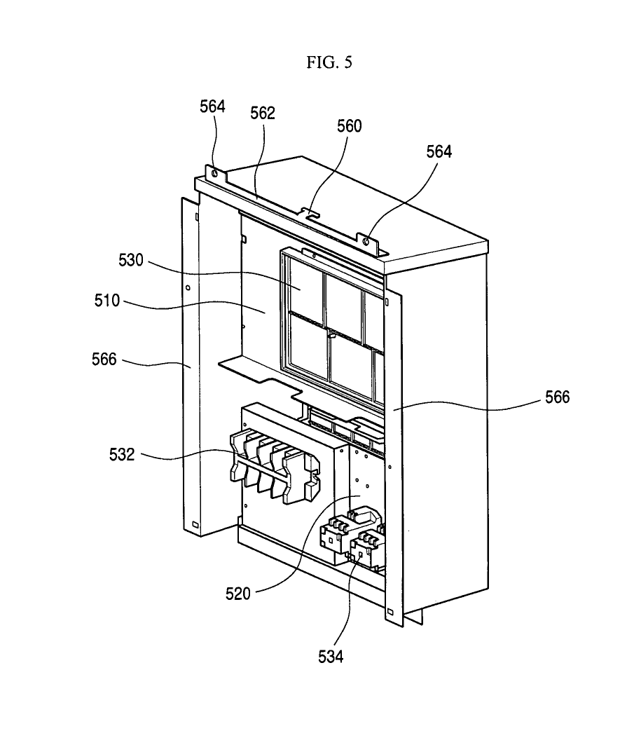

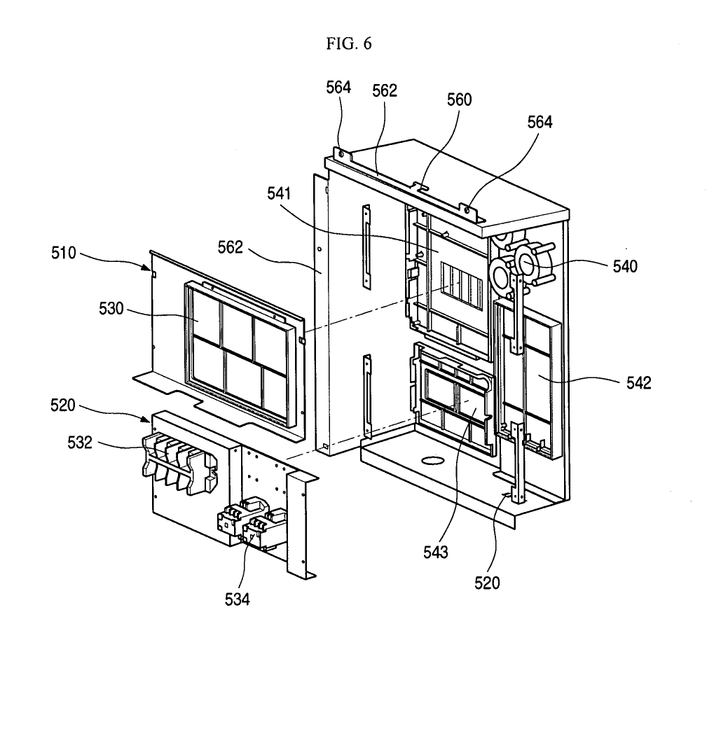

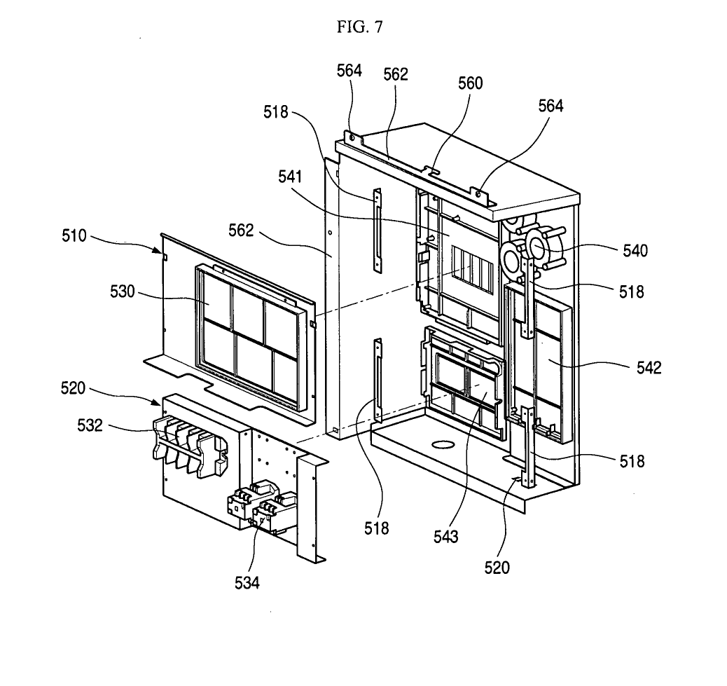

FIGS. 4 to 7 show the structure of a control box 500 in detail. That is, in FIGS. 4 and 5, the front surface and right section are shown, FIG. 6 is an exploded perspective view showing the front of a control box detached, and FIG. 7 is an exploded perspective view showing the internal structure of the control box 500.

As shown in the diagrams, an inspection window 501 is formed at the front of the control box 500. The inspection window 501 allows the state of the air conditioner to be inspected. A plurality of components such as a display 501a is further installed in the inspection window 501. The display 501a is a portion displaying the state of the air conditioner.

The inspection window 501 is formed in a position corresponding to the position of the servicing cover 516. Thus, when the servicing cover 516 is removed, the inspection window 501 is exposed to the outside through the servicing window 514.

The inside of the control box 500 is partitioned into a plurality of compartments in which electronic components are installed, and form air passages 502 to dissipate heat generated by the components.

In further detail, partitioning plates 510 and 512 are provided in the inner, central portion of the control box 500 to partition the space within the control box 500 into a plurality of compartments. As shown in the drawings, the partitioning plates 510 and 512 include an upper supporting plate 510 and a lower supporting plate 512 that are provided at the upper and lower portions of the control box, respectively.

The upper supporting plate 510 and the lower supporting plate 512 have rectangular flat plate shapes, and partition the inner space of the control box 500 roughly into a frontal (the left side, in FIG. 5) compartment, and a rear (the right side, in FIG. 5) compartment.

In FIG. 5, the upper supporting plate 510 and the lower supporting plate 512 are installed to be separated from one another. Alternately, however, the upper supporting plate 510 and the lower supporting plate 512 may be connected or integrally formed.

Further, partitioning plate mounting brackets 518 (in FIG. 7) are provided in the control box 500, for the partitioning plates 510 and 512 to be fixed and mounted thereon. The partitioning plate mounting brackets 518 are installed at the left and right sides of the control box, respectively, facing one another, and respectively fix the left and right ends of the partitioning plates 510 and 512.

Between the partitioning plates 510 and 512 (or the upper supporting plate 510 and the lower supporting plate 512) and the rear surface (the right side in FIG. 5), a predetermined space is defined. An air passage is defined vertically by the space. That is, an air passage 502 is formed, through which air from the outside that enters an inlet 520 (to be described below) ascends.

In more detail, air that enters through one end (the lower end) of the control box 500 passes along the air passage 502 and is discharged through the other end (the upper or rear end).

Accordingly, the inlet 520 and an outlet 522, for air entry and discharge, are respectively formed in the control box 500. The inlet 520 and outlet 522 are defined in different surfaces. That is, the inlet 520 is formed vertically through the lower surface of the control box 500, and the outlet 522 is formed from front to rear through the rear surface (the right surface in FIG. 5) at the upper portion of the control box 500.

In addition, a rain blocker (not shown) for preventing the entry of rainwater is further formed on the outlet 522. That is, because rainwater can enter the control box 500 from the outside through the outlet 522 formed at the rear surface (or right surface in FIG. 5) of the control box 500, the rain blocker, for preventing infiltration of rainwater, is formed to extend rearward on the outlet 522.

The rain blocker may be sloped so that its position rises gradually toward the rear (the right in FIG. 5). This is to allow air discharged rearward (to the right in FIG. 5) through the outlet 522 to be smoothly expelled upward from the outdoor unit 10.

A plurality of electronic components is installed within the control box 500. Of these, the components that generate comparatively more heat are installed proximately to the blower fan 400 that forcibly induces flow of air. That is, the components that generate comparatively more heat are mounted at the upper portion within the control box 500 in proximity to the blower fan 400.

Specifically, a main printed circuit board (PCB) 530, a terminal block 532, and a magnet switch (SW) 534 are installed in the front portion (the left side in FIG. 5) of the control box 500. That is, a main controller 530 is installed on the upper supporting plate 510 provided at the top, and the terminal block 532 and magnet S/W 534, etc. are installed on the lower supporting plate 512 provided at the bottom.

Furthermore, components such as a reactor 540 and inverter controller 541, a noise filter 542, and a fan controller 543 are installed in the rear portion (the right side in FIG. 5) of the control box 500. That is, the reactor 540 and inverter controller 541 are installed at the rear (the right side in FIG. 5) surface of the control box 500, and the noise filter 542 and the fan controller 543 are installed at the lower portion thereof.

Moreover, a heat sink 550 for dissipating heat is provided at the rear surface (the left surface in FIG. 5) of the control box 500. The heat sink 550 includes a plurality of heat dissipating fins, and projects rearward (to the left in FIG. 5) from the control box 500.

A heat pipe 552 through which refrigerant flows is located within the heat sink 550. The heat pipe 552 consists of a thin pipe that extends vertically, and refrigerant is filled inside the heat pipe 552.

Accordingly, the refrigerant filled in the heat pipe 552 flows vertically to uniformly transfer heat to the heat sink 550 in a vertical direction. Thus, the heat sink 550 may be provided in plurality, so that heat can be dissipated evenly along the entire surface area of the heat sink 550.

A plurality of heat dissipating ribs 544 is further provided at the rear end (the right end in FIG. 5) of the reactor 540, to support the reactor 540 and aid in heat dissipation.

Further, the control box 500 is hooked and fixed onto the frame assembly 300. That is, the top end of the control box 500 is hooked and fastened to the frame assembly 300, and the front surface is fastened to the front right panel 212.

The top end of the control box 500 includes a catching rib 560 for hooking onto the frame assembly 300, and a fastening end 562 for fastening to the frame assembly 300.

In further detail, the fastening end 562 protrudes upward from the leading upper edge of the control box 500, and the catching rib 560 bent and extending rearward is formed at the central upper end of the fastening end 562.

In addition, either end of the fastening end 562 respective defines a fastening hole 564 in which a screw fastens, and a catching slot (not shown) is recessed rearward into the leading end of the frame assembly 300 for the catching rib 560 to insert into.

Thus, after the catching rib 560 is inserted in the catching slot (not shown) defined in the leading end of the frame assembly 300, screws may be used to fix the control box 500 to the frame assembly 300.

A front fastening end 566 is formed at both the left and right side surfaces of the control box 500. The front fastening end 566 is tightly fixed by means of the screw to the front right panel 212.

The flow of air in an outdoor unit of an air conditioner configured above according to the present disclosure will be addressed in detail below.

First, referring to FIG. 3, the overall flow of air throughout the inside of the outdoor unit 10 is an upward airflow within the outdoor unit 10, induced by the rotation of the blower fan 400.

Accordingly, the outdoor air flows into the outdoor unit 10 through the rear grill 270, left grill 252, and right grill 262. The air is suctioned by the blower fan 400, moves upward to flow into the shrouds 420 and 422, and is discharged upward through the outlet grill G.

Here, external air contacts the outer surface of the control box 500 in a primary stage, and during this process, heat exchange occurs by means of the heat sink 550 formed on the outside of the control box 500. Also, the heat pipe 552 within the heat sink 550 increases the heat exchanging effectiveness of the heat sink 550 (see FIG. 5).

Next, FIG. 5 will be referred to in describing the flow of air within the control box 500. Here, the blower fan 400 forcibly circulates airflow in an upward direction, and the discharging of air through the outlet 522.

Accordingly, air is suctioned through the inlet 520, and the air suctioned through the inlet 520 flows upward through the air passage 502, after which it passes through the outlet 522 to be discharged to the rear (the right side in FIG. 5) of the control box 500. Then, the air enters the shrouds 420 and 422, and is discharged to the upper portion of the outdoor unit 10.

To describe the installation process of the control box 500, first, the catching rib 560 formed on the control box 500 is inserted into the catching slot (not shown) defined in the leading end of the frame assembly 300. Thus, the upper end of the control box 500 catches on the frame assembly 300.

Next, a screw is inserted and fastened in the fastening hole 564 of the fastening end 562. Thus, the upper end of the control box 500 is firmly fixed to the frame assembly 300.

Then, a screw is used to fasten a front fastening end 566 of the control box 500 to the front right panel 212. Through this procedure, the control box 500 is firmly fixed to the frame assembly 300 and the front right panel 212.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An outdoor unit for an air conditioner, comprising a control box including a plurality of built-in electronic components, wherein those of the electronic components generating more heat are installed in proximity to a blower fan that forcibly circulates air.

2. The outdoor unit according to claim 1, wherein the control box further comprises a partitioning plate provided within the control box to partition an inner space of the control box into a plurality of compartments, the partitioning plate fixed at both side edges to partitioning plate mounts.

3. The outdoor unit according to claim 2, wherein rear surfaces of the partitioning plate and the control box define an airflow passage therebetween, through which air flows.

4. The outdoor unit according to claim 2, wherein components generating less heat are installed at a front portion within the control box, and components generating more heat are installed at a rear portion within the control box.

5. The outdoor unit according to claim 4, wherein the control box further comprises:
a main PCB (printed circuit board), a terminal block, and a magnet switch installed in the front portion; and
a reactor, an inverter controller, a noise filter, and a fan controller installed in the rear portion.

6. The outdoor unit according to claim 5, wherein the control box further comprises a heat sink for dissipating heat provided on a rear surface of the control box.

7. The outdoor unit according to claim 6, wherein the heat sink comprises a built-in heat pipe through which refrigerant flows.

8. An outdoor unit for an air conditioner, comprising:
a front panel defining a front exterior of the outdoor unit; and
a control box in which a plurality of electronic components is disposed,
wherein the front panel defines a servicing window to allow manipulation of the control box from a front exterior, and the control box is provided with an inspection window at a front surface thereof to enable inspection of a state of the air conditioner.

9. The outdoor unit according to claim 8, wherein the servicing window is selectively covered with a servicing cover.

10. The outdoor unit according to claim 8, wherein the inspection window comprises a display displaying the state of the air conditioner.

11. An outdoor unit for an air conditioner, comprising:
a cabinet defining an overall exterior of the outdoor unit;
a blower fan forcing an upward discharging of air;
a frame assembly provided within the cabinet to support the blower fan; and
a control box provided at a side of the frame assembly, and including a plurality of electronic components within,
wherein the control box is hooked and fixed to the frame assembly.

12. The outdoor unit according to claim 11, wherein the control box further comprises:
a catching rib at an upper end of the control box to catch on the frame assembly; and
a fastening end at the upper end of the control box to fasten to the frame assembly.

13. The outdoor unit according to claim 12, wherein the fastening end is formed to protrude upward from a leading portion of the upper end of the control box.

14. The outdoor unit according to claim 13, wherein the catching rib is bent downward and extends from a central upper portion of the fastening end.

15. The outdoor unit according to claim 14, wherein the frame assembly defines a catching slot recessed rearward into a leading end of the frame assembly, and the catching rib inserts in the catching slot.
